(19) United States
(12) Patent Application Publication
(10) Pub. No.: US 2025/0051961 A1
(43) Pub. Date: Feb. 13, 2025

(54) METHOD OF MANUFACTURING SILICON EPITAXIAL SUBSTRATE AND SILICON EPITAXIAL SUBSTRATE

(71) Applicant: GLOBALWAFERS JAPAN CO., LTD., Kitakanbara-gun, Niigata (JP)

(72) Inventors: Takeshi SENDA, Kitakanbara-gun, Niigata (JP); Shingo NARIMATSU, Kitakanbara-gun, Niigata (JP); Hisashi MATSUMURA, Kitakanbara-gun, Niigata (JP); Takashi ISHIKAWA, Kitakanbara-gun, Niigata (JP)

(73) Assignee: GLOBALWAFERS JAPAN CO., LTD., Kitakanbara-gun, Niigata (JP)

(21) Appl. No.: 18/721,810

(22) PCT Filed: Jun. 28, 2022
(86) PCT No.: PCT/JP2022/025687

§ 371 Date: Jun. 19, 2024

(30) Foreign Application Priority Data
Dec. 22, 2021 (JP) 2021-208506

(51) Int. Cl. C30B 29/06; C30B 15/04; C30B 25/20; C30B 33/02

(52) U.S. Cl. CPC C30B 29/06; C30B 15/04; C30B 25/20; C30B 33/02

(57) ABSTRACT

The disclosed silicon epitaxial substrate production method and silicon epitaxial substrate prevent the occurrence of stacking fault. The method includes growing a silicon single crystal to which phosphorus is added as a dopant and of which the electrical resistivity is adjusted to 0.6 to 1.0 mΩ·cm using the Czochralski method. The silicon single crystal is monitored for a 700-600° C. passage time during cooling. The silicon single crystal is sliced and the sliced product is placed in an epitaxial growth furnace. The method further includes retaining the furnace temperature of the epitaxial growth furnace for 120 seconds to 300 seconds at a temperature ranging from 750° C. to 900° C. inclusive when the 700-600° C. passage time is less than 300 minutes and at a temperature ranging from 900° C. to 1000° C. inclusive when the 700-600° C. passage time is 300 minutes or more. Epitaxial growth is performed following the retention step.

### TECHNICAL FIELD

This invention relates to a method of manufacturing a silicon epitaxial substrate and a silicon epitaxial substrate.

### BACKGROUND ART

For epitaxial silicon wafers for power metal oxide semiconductor field effect transistors (MOSFET), low electrical resistivity of the substrate is required, and to date, substrates with an electrical resistivity of 1 mΩ·cm or less are known. To lower the substrate electrical resistivity of silicon wafers, arsenic (As) and antimony (Sb) are added to molten silicon as n-type dopants for electrical resistivity adjustment during the silicon single-crystal ingot pulling process. However, since these dopants are very volatile, it is difficult to increase the dopant concentration in silicon single-crystals, and as a result, the electrical resistivity of the substrate cannot be sufficiently lowered. Therefore, n-type dopant species are shifted from As and Sb to phosphorus (P), whose concentration is about 1×10²⁰ atoms/cm³.

However, it is known that when phosphorus is added at a high concentration during single crystal ingot growth to achieve an electrical resistivity of e.g., 1.1 mΩ·cm or less, when epitaxial layers are grown on silicon wafers cut from such single crystal ingots, a large number of stacking faults (hereinafter also referred to as SFs) occur in the epitaxial layer. These stacking faults appear as steps on the surface of the epitaxial silicon wafer and are detected as an increase in the number of light point defects (LPDs) on the wafer surface.

For example, patent literature 1 and non-patent literature 1 and 2 disclose techniques for producing a silicon single crystal having an electrical resistivity of 0.6 to 1.0 mΩ·cm by setting a passage time of less than 300 min at 700° C. to 600° C. in the cooling process during the growth of silicon single crystals to reduce the number of the stacking faults. In addition, patent literature 2 describes that the number of stacking faults is reduced by subjecting the wafers to a heat treatment at 700 to 1050° for 30 to 450 s prior to epitaxial growth.

### CITATION LIST

### Patent Literature

PTL 1: JP-A-2021-109807
PTL 2: JP-A-2019-186449

### Non-Patent Literature

NPL 1: Senda, T. et al., “Atomic structures of grown-in Si—P precipitates in red-phosphorus heavily doped CZ Si crystals”, (7p-PB6-5), The 78th JSAP Autumn Meeting, 2017;
NPL 2: Senda, T. et al., “Formation behavior of Si—P precipitates in CZ—Si crystals with heavily doped phosphorus”, (15p-D411-1), The 67th JSAP Spring Meeting, 2020.

### SUMMARY OF INVENTION

### Technical Problem

The occurrence of stacking faults in the epitaxial layer is caused by phosphorus and silicon precipitates (Si—P defects) formed during the crystal growth process of the substrate crystal, which is considered to be the starting point for the occurrence of stacking faults during epitaxial growth.

Therefore, in order to suppress the occurrence of stacking faults, it is necessary to inhibit the occurrence of Si—P defects during the crystal growth process and to prevent Si—P defects from becoming the starting point for the occurrence of stacking faults in a cooperated manner.

However, for example, the technique of PTL 1 focuses on the crystal growth process, and the technique of PTL 2 focuses on the epitaxial growth process and does not reflect the crystal growth history on the epitaxial growth process.

The object of the present invention is to provide a method of manufacturing a silicon epitaxial substrate that suppresses the occurrence of stacking faults and a silicon epitaxial substrate, in view of the above problems.

### Solution to Problem

The method of manufacturing a silicon epitaxial substrate to solve the above problem includes a step of growing a silicon single crystal by the Czochralski method the electrical resistivity of which is adjusted to 0.6 to 1.0 mΩ·cm by adding phosphorus as a dopant, a step of monitoring the passage time from 700° C. to 600° C. when the silicon single crystal is cooled, a step of slicing a silicon single crystal and placing it in an epitaxial growth furnace, a step of holding at low temperature of the epitaxial growth furnace for 120 s to 300 s at a temperature of 750° C. or more and 900° C. or less when the passage time is less than 300 min at 700° C. to 600° C., or at a temperature of 900° C. or more and 1000° C. or less when the passage time is 300 min or more at the above temperature range, and a step of epitaxial growth in which epitaxial growth is performed after the step of holding at low temperature.

It can be assumed that in the epitaxial growth step, Si—P defects formed during the cooling of the silicon single crystal have adverse effects (remain or increase) on the strain in the crystal structure caused by Si—P precipitates if the dissolution of the phosphorus contained in the Si—P precipitates into the surroundings and the escape of the dissolved phosphorus from the substrate occur simultaneously. According to the method of manufacturing a silicon epitaxial substrate of the above construction, the residual strains in the crystal structure in the surface layer of the substrate are reduced by continuously and in a steady state performing the process of dissolving the phosphorus contained in the Si—P precipitates into the surroundings and the process of escaping the dissolved phosphorus (P) from the substrate, whereby the occurrence of stacking faults can be suppressed.

In addition, in the above step of holding at low temperature, it is desirable to hold the furnace temperature of the epitaxial growth furnace for 120 s to 300 s at a temperature of 750° C. or more and 875° C. or less when the passage time is less than 200 min at 700° C. to 600° C., or at a temperature of 825° C. or more and 900° C. or less when the passage time is 200 min or more and less than 300 min.

Furthermore, between the above step of holding the furnace temperature and the step of epitaxial growth, it is desirable to carry out etching with hydrogen chloride at a temperature of 1150° C. or more and less than 1200° C., and then to carry out hydrogen heat treatment is carried out at a temperature of 1150° C. or more and less than 1200° C. This effectively eliminates the silicon lattice strain as a residue and the occurrence of stacking faults can be further reduced.

Before the above step of holding at low temperature, a chemical oxide film having a thickness of 0.5 nm or more is preferably formed with ozone water. In a step of holding at low temperature, it is important that the oxide film on the substrate surface is stable, and the ozone oxide film is preferred.

The length of the tail portion of the ingot produced at the last stage of the step of single crystal growth is preferably 0 to 50 mm. By making the length of the tail portion 0 to 50 mm, it is possible to reduce the pulling-up time of a silicon single crystal at a temperature of 700° C. to 600° C., which is the growth temperature of Si—P defects.

When the method of manufacturing the above silicon epitaxial substrate is described from the viewpoint of products, the product is a silicon epitaxial substrate on which an epitaxial layer is grown on a semiconductor substrate having the electrical resistivity adjusted to 0.8-0.9 mΩ·cm and the density of Si—P precipitates having a maximum edge of 35 nm or more of less than 3×10¹¹/cm³ and is the silicon epitaxial substrate that is held at 750° C. to 900° C. for 120 seconds to 300 seconds before the silicon epitaxial layer is grown.

### Advantageous Effects

In accordance with each feature of the present invention, it is possible to provide a method of manufacturing a silicon epitaxial substrate in which the occurrence of stacking faults is suppressed and a silicon epitaxial substrate.

### BRIEF DESCRIPTION OF DRAWINGS

FIG. 1 is a schematic structural view of a pulling-up apparatus for the Czochralski method;

FIG. 2 is a schematic structural view of an epitaxial growth furnace;

FIG. 3 is a graph showing the holding temperature dependence of stacking faults with a passage time at a temperature of 700° C. to 600° C. of less than 200 min;

FIG. 4 is a graph showing the holding temperature dependence of stacking faults with a passage time at a temperature of 700° C. to 600° C. for 200 min or more to less than 300 min;

FIG. 5 is a graph showing the holding temperature dependence of stacking faults with a passage time at a temperature of 700° C. to 600° C. of 300 min or more;

FIG. 6 shows the dependence of stacking fault on the passage time at the temperature from 700° C. to 600° C. in crystal growth;

FIG. 7 shows the dependence of Si—P precipitates on the passage time at the temperature from 700° C. to 600° C. in crystal growth;

FIG. 8 is a graph showing the relationship between the occurrence of the stacking faults and the density of Si—P precipitates in the example;

FIG. 9 is a graph showing the relationship between the occurrence of the stacking faults and the density of the Si—P precipitates in the comparative example; and

FIG. 10 is a flow chart illustrating the method of manufacturing silicon epitaxial substrates.

### DESCRIPTION OF EMBODIMENTS

The following is a description of the experiment of the invention with reference to the drawings. However, the invention is not limited to the experiments described below. In each drawing, identical or corresponding elements are indicated by the same symbol where appropriate. It should also be noted that the drawings are schematic, and the relationship between the dimensions of each element and the ratio of each element may differ from reality. Even within the drawings, there may be portions in which the relationship of dimensions and proportions differ from each other.

First, the pulling-up apparatus and the epitaxial growth furnace to be used for the method of manufacturing silicon epitaxial substrates according to the embodiment of the present invention will be described.

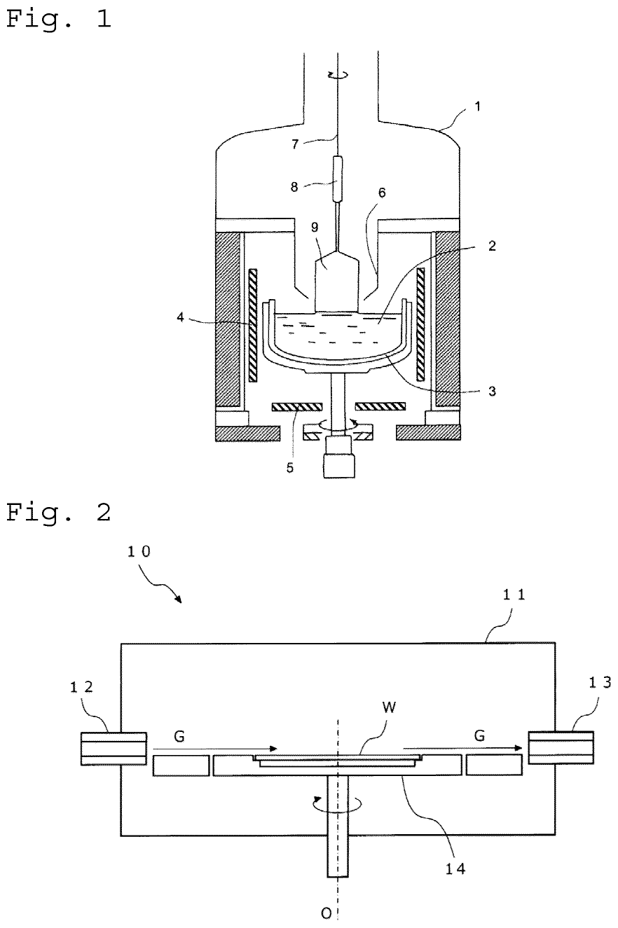

FIG. 1 is a schematic structural view of a pulling-up apparatus for the Czochralski method. In the pulling-up apparatus shown in FIG. 1, a quartz crucible 3 filled with raw material melt 2 is rotatably installed in the center of the furnace 1. On the periphery of the quartz crucible 3, a side heater 4 for heating the quartz crucible 3 from the side periphery and a bottom heater 5 for heating it from the bottom are installed. A radiation shield 6 is provided above the quartz crucible 3 for controlling, for example, the temperature of the raw material melt 2 in the quartz crucible 3 and the single crystal 9 to be grown.

In the single crystal pulling-up apparatus of the Czochralski method, a seed crystal 8 held at the lower end of the wire 7 is dipped into the liquid surface of the raw material melt 2 in the quartz crucible 3, a single crystal 9 is grown by pulling up the wire 7 while rotating the quartz crucible 3 and the seed crystal 8, respectively. Here, it is assumed that phosphorus is added as a dopant to the raw material melt 2 and the electrical resistivity is controlled to be 0.6 mΩ·cm to 1.0 mΩ·cm.

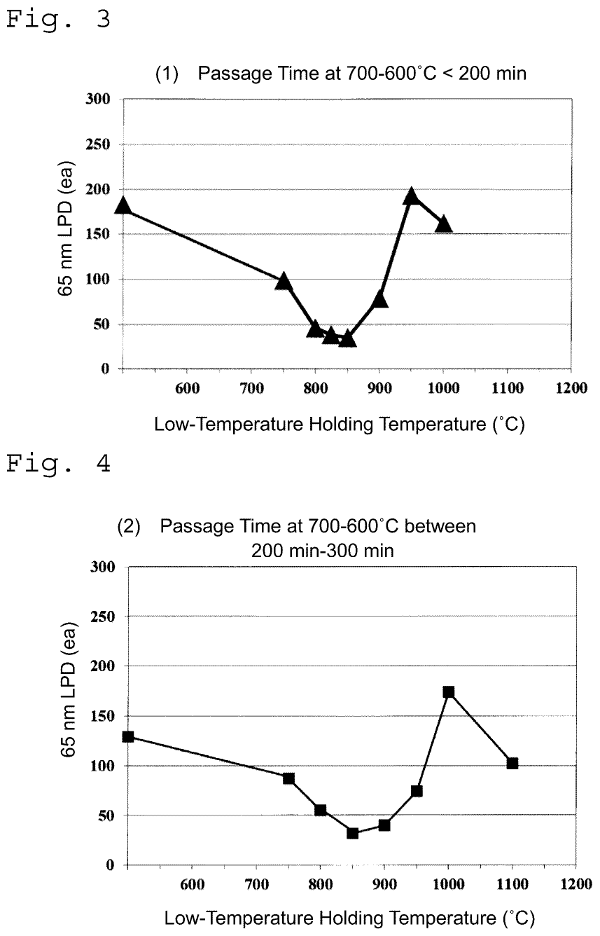

FIG. 2 is a schematic structural view of an epitaxial growth furnace. As shown in FIG. 2, in the epitaxial growth furnace 10, a semiconductor substrate W is placed on a susceptor 14 installed in the chamber 11. Then, the susceptor 14 and semiconductor substrate W are rotated in a predetermined direction about a rotation axis O. Then, while the semiconductor substrate W is heated to a predetermined temperature by a heater outside the chamber 11, the reaction gas G is supplied horizontally from the reaction gas supply pipe 12 to the exhaust pipe 13, thereby growing an epitaxial layer on the surface of the semiconductor substrate W.

Here, the process by which Si—P defects become the starting point for the occurrence of stacking faults is considered. In the present invention, the occurrence of stacking faults is suppressed based on this consideration.

When the temperature of the silicon single crystal is high, the phosphorus can dissolve in the silicon single crystal at a higher concentration. On the other hand, as the temperature becomes lower, it becomes difficult for the phosphorus to dissolve in the silicon single crystal at a higher concentration.

Therefore, in the process of growing silicon single-crystals by the Czochralski method, even though it is possible to dissolve phosphorus at a high concentration in the raw material melt 2, phosphorus that cannot be fully dissolved in the single crystal 9 forms precipitates in the process of pulling the single crystal 9 from the raw material melt 2. In particular, in single crystal 9 doped with a high concentration of phosphorus to lower the electrical resistivity, the concentration is about 1×10²⁰ atoms/cm³, and precipitates of phosphorus and silicon (Si—P precipitates) are formed in the temperature range of 600° C. to 700° C. of single crystal 9, as was found in PTL 1.

Meanwhile, in the epitaxial growth process, the temperature in the furnace of the epitaxial growth furnace 10 is 1000° C. or higher, so the Si—P precipitates formed in the crystal growth process are dissolved and diffused again, but strain remains in the crystal structure at the trace where Si—P precipitates were formed, which is considered to be the starting point of stacking fault occurrence.

If the dissolution of phosphorus contained in Si—P precipitates into the surroundings and the escaping of the dissolved phosphorus (P) out of the substrate occur simultaneously, it is considered to have an adverse effect (remain or increase) on the strain of the crystal structure caused by the Si—P precipitates. Therefore, the following verification experiments were conducted based on the hypothesis that the dissolution of phosphorus (P) contained in Si—P precipitates into the surroundings and the escaping of the dissolved phosphorus (P) from the substrate should be performed continuously and in a steady state to reduce residual strain of the crystal structure strain on the surface layer of the substrate.

### Verification Experiments 1

First, a phosphorus-doped silicon single crystal was grown by the Czochralski method controlled to have an electrical resistivity of 0.7 mΩ·cm to 0.9 mΩ·cm. The crystal orientation was <100>, the diameter was 200 mm, and the oxygen concentration was 0.9×10¹⁸ atoms/cm³.

When the crystal was grown, the crystal length of the tail of the ingot and the cooling time were controlled to set three passage time conditions at a temperature range from 700° C. to 600° C.:
(1) less than 200 min,
(2) 200 min or more and less than 300 min, and
(3) 300 min or more.

The corresponding silicon single crystals were then sliced, and an oxide film was deposited on the back and mirror-polished. The semiconductor substrates W were treated with 1 ppm ozone water, and a chemical oxide film having a thickness of 0.7 nm was formed on the surface.

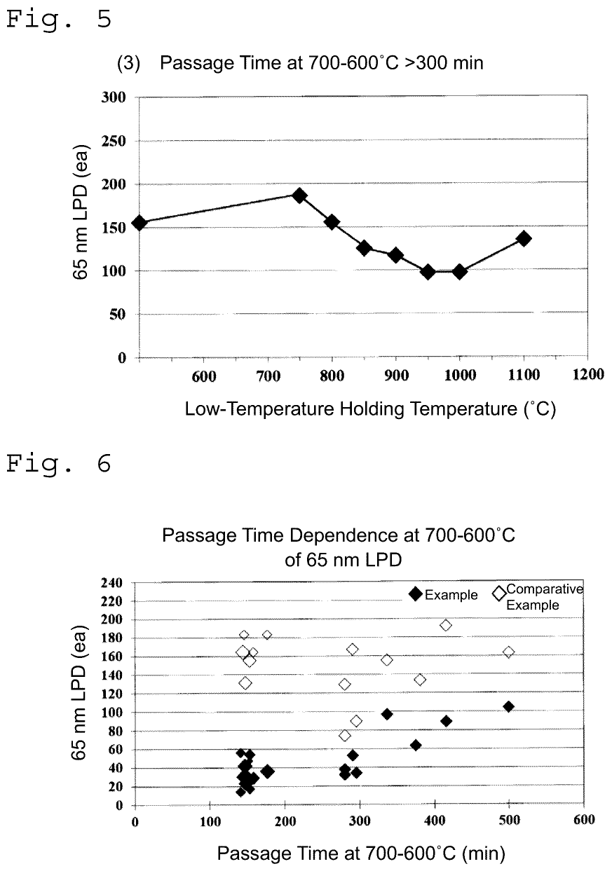

Then, the semiconductor substrates were placed in the epitaxial growth furnace, and the occurrence of stacking faults, i.e., the number of light point defects (LPD), was measured while varying the temperature conditions at a pre-stage of epitaxial growth. FIGS. 3 to 5 are graphs showing the holding temperature dependence of stacking faults with the passage time at 700° C. to 600° C. of (1) less than 200 min, (2) 200 min or more and less than 300 min, and (3) 300 min or more, respectively. The holding time at each temperature ranges from 120 s to 300 s, and the case without a low-temperature holding is plotted at the left end of the horizontal axis of the graph.

As can be understood by comparing the graphs of FIGS. 3 to 5, the holding temperature dependence of the stacking faults at the pre-stage of the epitaxial growth is downward convex regardless of the passage time at 700° C. to 600° C. in the crystal growth. That is, the optimum holding temperature at the pre-stage of the epitaxial growth is preferably in a certain temperature range, not too low or not too high.

Further, as can be understood by comparing the graphs of FIGS. 3 to 5, the optimum holding temperature at the pre-stage of the epitaxial growth shifts to higher temperatures as the passage time increases, depending on the passage time at 700° C. to 600° C. in the crystal growth. Specifically, the optimum holding temperature at the pre-stage of the epitaxial growth is 750° C. or more and 875° C. or less for the passage time at 700° C. to 600° C. in the crystal growth is for (1) less than 200 min, 825° C. or more and 900° C. or less for (2) 200 min or more and less than 300 min, and 900° C. or more and 1000° C. or less for (3) 300 min or more.

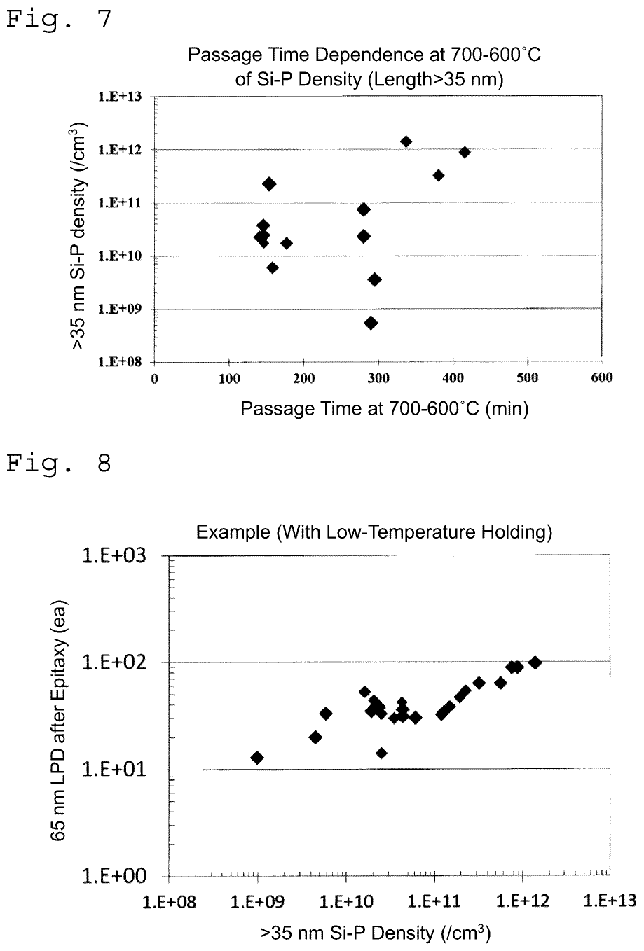

Further, as can be understood by comparing the graphs of FIGS. 3 to 5, the shapes of the graphs are very different when the passage time at 700° C. to 600° C. in the crystal growth is (1) less than 200 min, (2) 200 min or more and less than 300 min, and (3) 300 min or more. This is clearly shown by FIG. 6. FIG. 6 is a graph showing the passage time dependence at 700° C. to 600° C. in the crystal growth of the stacking faults. In the graphs shown in FIG. 6, the case of setting a low-temperature holding time at the pre-stage of the epitaxial growth is represented by the plot with filled marks, and the case of not setting a low-temperature holding time at the pre-stage of the epitaxial growth is represented by the plot with open marks.

As seen from the graphs in FIG. 6, setting a low-temperature holding time at the pre-stage of the epitaxial growth can reduce the occurrence of stacking faults, but when the passage time at 700° C. to 600° C. in the crystal growth exceeds 300 min, the reduction effect on the occurrence of stacking faults decreases.

Thus, when setting the low-temperature holding time at the pre-stage of the epitaxial growth, the low-temperature holding time can be considered to be classified according to whether the passage time at 700° C. to 600° C. in crystal growth exceeds 300 min. In other words, in the pre-stage of the epitaxial growth, the classification of the holding time at the low temperature is effective; the temperature is set to 750° C. or more and 900° C. or less when the passage time at 700° C. to 600° C. in crystal growth is less than 300 min and to 900° C. or more and 1000° C. or less when the passage time at 700° C. to 600° C. in crystal growth is 300 min or more, and the temperature of the epitaxial growth furnace is held for 120 s to 300 s.

### Verification Experiments 2

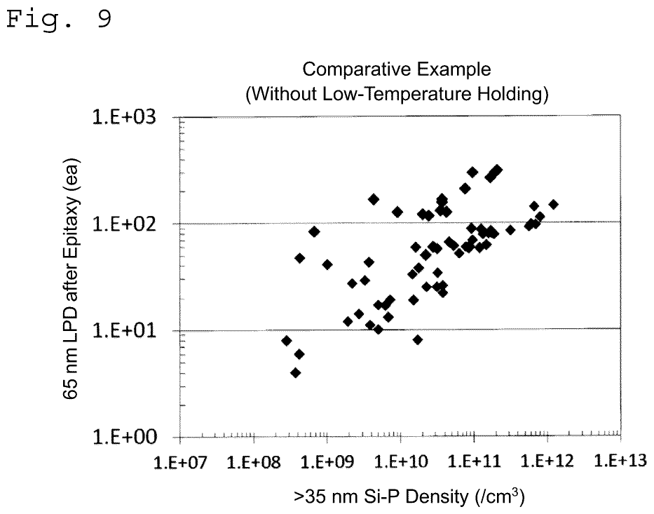

Next, the relationship between the Si—P precipitates formed during the step of crystal growth and the reduction in stacking faults is verified. FIG. 7 is a graph showing the dependence of the Si—P precipitates on the passage time at 700° C. to 600° C. in crystal growth. In the graph shown in FIG. 7, the horizontal axis is the passage time at 700° C. to 600° C. in crystal growth, and the vertical axis is the density (/cm³) of the Si—P precipitates having a size larger than 35 nm.

As seen from FIG. 7, the density of the Si—P precipitates having a size larger than 35 nm can be suppressed to less than 3×10¹¹, by setting the passage time at 700° C. to 600° C. in crystal growth to less than 300 min. That is, by controlling the passage time at 700° C. to 600° C. in crystal growth, it is possible to suppress the density of Si—P precipitates to a low level from the point of view of the manufacturing method.

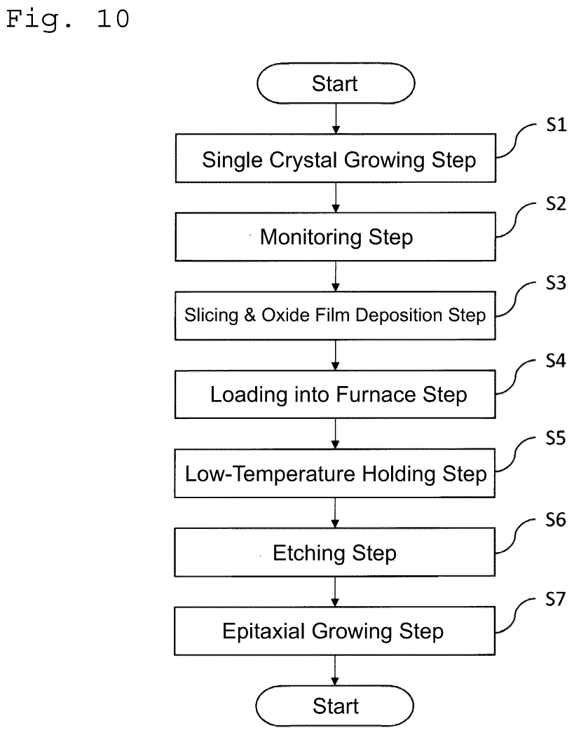

Meanwhile, there is a close relationship between the density of Si—P precipitates and the low-temperature holding at the pre-stage of epitaxial growth. FIGS. 8 and 9 are graphs showing the occurrence of stacking faults and the density of Si—P precipitates with and without the low-temperature holding at the pre-stage of epitaxial growth, respectively. The graphs in FIGS. 8 and 9 are the measurement results, where the horizontal axis is the density of Si—P precipitates (/cm³) having a size larger than 35 nm before the epitaxial growth and the vertical axis is the occurrence of stacking faults after the epitaxial growth in terms of light point defect (LPD).

As can be understood from FIG. 8, by reducing the density of Si—P precipitates having a size larger than 35 nm before epitaxial growth to less than 3×10¹¹/cm³, the light point defects (LPD) after epitaxial growth can be further reduced.

As can be understood by comparing FIGS. 8 and 9, the dispersion of the relationship between the occurrence of stacking faults and the density of Si—P precipitates is small when the low-temperature holding is carried out at the pre-stage of epitaxial growth. This means that the occurrence of stacking faults can be more effectively reduced not only by controlling the passage time at 700° C. to 600° C. in crystal growth but also by combining the low-temperature holding at the pre-stage of the epitaxial growth. Since the dispersion of the relationship between the occurrence of stacking faults and the density of Si—P precipitates is small, not only can the occurrence of stacking faults be reduced, but the variation from product to product can also be reduced.

### Summary of Manufacturing Method

FIG. 10 is a flow chart illustrating the method of manufacturing silicon epitaxial substrates, in which the results of the verification experiments above are reflected. As shown in FIG. 10, the method of manufacturing silicon epitaxial substrates includes a step of growing a single crystal (single crystal growing step) (S1), a step of monitoring (monitoring step) (S2), a step of slicing and depositing an oxide film (slicing & oxide film deposition step) (S3), a step of loading into a furnace (loading into furnace step) (S4), a step of holding at a low temperature (low-temperature holding step) (S5), a step of etching (etching step) (S6), and a step of epitaxial growing (epitaxial growing step) (S7).

In the single crystal growing step (S1), a silicon single crystal is grown by a pulling-up apparatus using the Czochralski method. Phosphorus is added as a dopant to a raw material melt, and the silicon single crystal having an electrical resistivity controlled to be 0.6 mΩ·cm to 1.0 mΩ·cm is used.

In the monitoring step (2), the passage time at 700° C. to 600° C. is monitored when the silicon single crystal is cooled. The length of the tail portion of the ingot, which is formed at the last stage of the single crystal growing step, is preferably 0 mm to 50 mm. By adjusting the tail length to 0 mm to 50 mm, the pull-up time of the silicon single crystal at a temperature of 700° C. to 600° C. which is the growth temperature of Si—P defects can be shortened.

In the step of slicing and oxide film deposition (S3), the silicon single crystal is sliced into substrates, and an oxide film is deposited on the (back side) thereof and the other side (front side) is mirror-polished. In addition, an oxide film is deposited on the front side surface of the substrate. Specifically, the substrates are treated with ozone water to preferably form a chemical oxide film having a thickness of 0.7 nm on the front surface. As described above, it is important that the oxide film on the substrate surface is stable in the subsequent low-temperature holding step (S5), and the ozone oxide film is suitable.

In the step of loading into furnace (S4), the silicon semiconductor substrates are loaded into the epitaxial growth furnace.

In the low-temperature holding step (S5), the temperature of the epitaxial growth furnace is raised; the temperature, which is lower than that for the epitaxial growth, is held for 120 s to 300 s. Specifically, the temperature is preferably set to 750° C. or more and 900° C. or less when the passage time at 700° C. to 600° C. is less than 300 min at the time of cooling the silicon single crystal monitored in the monitoring step (S2) and to 900° C. or more and 1000° C. or less when the passage time at 700° C. to 600° C. is 300 min or more.

Furthermore, in the low-temperature holding step (5), temperature is more preferably set to 750° C. or more and 875° C. or less when the passage time at 700° C. to 600° C. is less than 200 min at a time of cooling the silicon single crystal monitored in the monitoring step (S2) and to 825° C. or more and 900° C. or less when the passage time at 700° C. to 600° C. is 200 min or more and less than 300 min.

In the etching step (S6), etching is performed with hydrogen chloride at a temperature of 1150° C. or more and less than 1200° C., and then heat treatment is performed with hydrogen at a temperature of 1150° C. or more and less than 1200° C. This allows the silicon lattice strain as a residual strain to be effectively eliminated, thereby further reducing the occurrence of stacking faults.

In the epitaxial growth step (S7), a silicon epitaxial layer is deposited at a temperature of 1100° C. to 1150° C.

### INDUSTRIAL APPLICABILITY

As described above, the method of manufacturing a silicon epitaxial substrate according to the present invention is useful as a method of manufacturing a silicon epitaxial substrate that allows the suppression of the occurrence of stacking faults; particularly suitable for substrates that are required to have a low electrical resistivity, for power MOSFET substrates, for example.

### REFERENCE SIGNS LIST

1 furnace
2 raw material melt
3 quartz crucible
4 side heater
5 bottom heater
6 radiation shield
7 wire
8 seed crystal
9 single crystal
10 epitaxial growth furnace
11 chamber
12 reaction gas supply pipe
13 exhaust pipe
W semiconductor substrate

1. A method of manufacturing a silicon epitaxial substrate, comprising:
a step of growing a silicon single crystal by the Czochralski method the electrical resistivity of which is adjusted to 0.6 to 1.0 mΩ·cm by adding phosphorus as a dopant;
a step of monitoring a passage time from 700° C. to 600° C. when the silicon single crystal is cooled;
a step of slicing a silicon single crystal and placing it in an epitaxial growth furnace;
a step of holding the furnace temperature of the epitaxial growth furnace for 120 s to 300 s at a temperature of 750° C. or more and 900° C. or less when the passage time is less than 300 min at 700° C. to 600° C., or at a temperature of 900° C. or more and 1000° C. or less when the passage time is 300 min or more at the above temperature range; and
a step of epitaxial growth after the low-temperature holding step.

2. The method of manufacturing a silicon epitaxial substrate according to claim 1, wherein
in the step of holding at low temperature, the furnace temperature of the epitaxial growth furnace is held for 120 s to 300 s at a temperature of 750° C. or more and 875° C. or less when the passage time is less than 200 min at 700° C. to 600° C., or at a temperature of 825° C. or more and 900° C. or less when the passage time is 200 min or more and less than 300 min.

3. The method of manufacturing a silicon epitaxial substrate according to claim 1,
wherein
between the step of holding at low temperature and the step of epitaxial growth, etching is performed with hydrogen chloride at a temperature of 1150° C. or more and less than 1200° C., and then hydrogen heat treatment is performed at a temperature of 1150° C. or more and less than 1200° C.

4. The method of manufacturing a silicon epitaxial substrate according to claim 1,
wherein
before the step of holding at low temperature, a chemical oxide film having a thickness of 0.5 nm or more is formed with ozone water.

5. The method of manufacturing a silicon epitaxial substrate according to claim 1,
wherein
the length of the tail portion of the ingot produced at the last stage of the step of single crystal growth is 0 to 50 mm.

6. A silicon epitaxial substrate whose electrical resistivity is adjusted to 0.8-0.9 mΩ·cm and whose density of Si—P precipitates having a maximum edge of 35 nm or more is less than 3×10¹¹/cm³,
wherein
before growing the silicon epitaxial layer, the silicon epitaxial substrate is held at a temperature of 750° C. or more and 900° C. or less for 120 s to 300 s.
